(19) United States
(12) Patent Application Publication
(10) Pub. No.: US 2026/0268995 A1
(43) Pub. Date: Sep. 10, 2026

(54) ELECTRONIC DEVICE SMART RAM BUILT IN SELF TEST

(71) Applicant: Texas Instruments Incorporated, Dallas, TX (US)

(72) Inventors: Vishal Diwan, BANGALORE (IN); Mihir Narendra Mody, BANGALORE (IN); Malav Shah, BANGALORE (IN); Rakesh Y C, BANGALORE (IN)

(21) Appl. No.: 19/070,619

(22) Filed: Mar. 5, 2025

(51) Int. Cl. G11C 29/18

(52) U.S. Cl. CPC G11C 29/18; G11C 2029/1806

(57) ABSTRACT

An electronic device includes a processor, a memory having a first memory bank and a second memory bank, and a device identifier stored in the electronic device and readable by the processor to identify a non-faulty one of the memory banks of the memory. A method includes testing a first memory bank and a second memory bank of a memory in an electronic device, determining a faulty one of the memory banks of the memory and a non-faulty one of the memory banks of the memory, and storing a device identifier in the electronic device that identifies the non-faulty one of the memory banks of the memory.

### BACKGROUND

Memory testing during electronic device manufacturing is typically performed after device packaging, such as using integrated or built-in self test (BIST) circuitry. However, any memory failure results in the device being scrapped, and the cost is high.

### SUMMARY

In one aspect, an electronic device includes a processor, a memory having first and second memory banks, and a device identifier stored in the electronic device and readable by the processor to identify a non-faulty one of the memory banks of the memory.

In another aspect, a method includes testing a first memory bank and a second memory bank of a memory in an electronic device, determining a faulty one of the memory banks and a non-faulty one of the memory banks of the memory, and storing a device identifier in the electronic device that identifies the non-faulty one of the memory banks of the memory.

In a further aspect, a system includes a memory having first and second memory banks in an electronic device and a processor configured to test the first memory bank and the second memory bank, determine a faulty one of the memory banks of the memory and a non-faulty one of the memory banks, and store a device identifier in the electronic device that identifies the non-faulty one of the memory banks of the memory.

### BRIEF DESCRIPTION OF THE DRAWINGS

FIG. 1 is a system diagram showing an electronic device having a multi-bank memory and an address translation circuit configurable according to a stored device identifier.

FIG. 1A is a schematic diagram showing the address translation circuit configured by an address translation data lookup table.

FIG. 2 is a flow diagram of an electronic device manufacturing method with memory self testing and device classification based on memory test result.

FIG. 3 is a flow diagram of a ROM firmware address translation circuit configuration method.

FIG. 4 is a flow diagram of a boot loader firmware address translation circuit configuration method.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material.

Unless otherwise stated, “about,” “approximately,” or “substantially” preceding a value means +/−10 percent of the stated value. One or more structures, features, aspects, components, etc., may be referred to herein as first, second, third, etc., such as first and second terminals, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

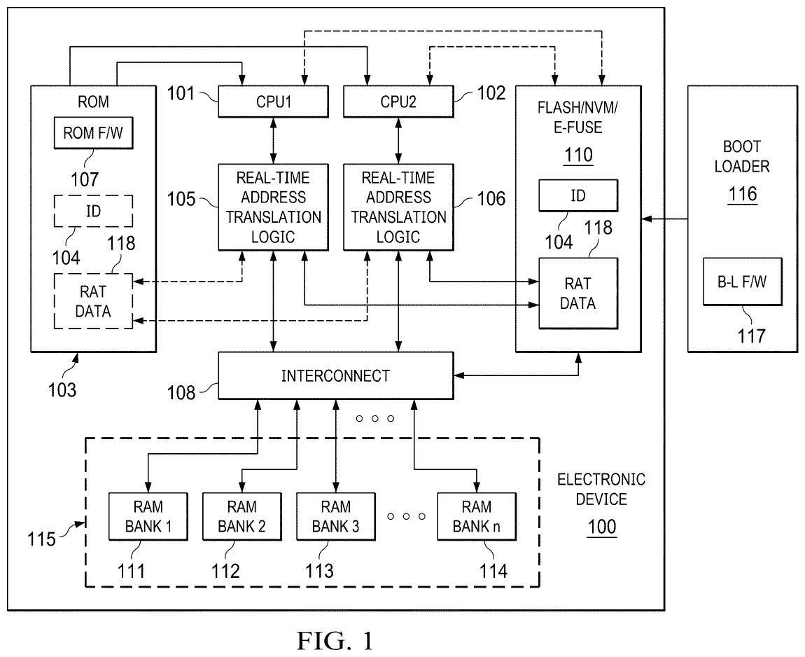

FIG. 1 shows a system for testing an installed electronic device 100 that has first and second processors 101 and 102 (e.g., labeled “CPU1” and “CPU2” in FIG. 1). The electronic device 100 can include a single die, or multiple dies (e.g., a system on chip or SoC) and can have any integer number processors. In one example, the electronic device 100 has separate dies for the processors 101 and 102 and one or more additional dies for random-access memory (RAM), although not a requirement of all possible implementations.

The electronic device 100 has a read-only memory 103 (e.g., labeled “ROM”). In one implementation, the ROM 103 includes a device identifier 104 (e.g., labeled “ID”) that is readable by one or both of the processors 101 and 102 and identifies one or more operational (e.g., non-faulty) RAM memory banks 111-114 of a multi-bank memory 115, sometimes referred to herein as a first memory. The other memories (e.g., ROM 103 and/or nonvolatile memory 110) can be referred to as a “second” memory. In the illustrated example, four RAM banks 111-114 are illustrated (e.g., labeled “RAM BANK 1”, “RAM BANK 2”, “RAM BANK 3”, . . . “RAM BANK n”). Any integer number n banks can be included in the multi-bank memory 115, where n is greater than or equal to 2.

The electronic device 100 includes address translation circuits 105 and 106 (e.g., labeled “REAL-TIME ADDRESS TRANSLATION LOGIC”) that are operatively coupled to the respective processors 101 and 102. The illustrated example includes a real-time address translation logic circuit 105, 106 for each corresponding processor 101, 102, although not a requirement of all possible implementations. In one example, the address translation circuits 105 and 106 are configurable and include programmed and/or programmable circuits (e.g., non-volatile memory registers, etc.). The individual address translation circuits 105 and 106 also include circuitry (not shown) to translate an address received from the corresponding processor 101, 102 and provide a translated address for accessing an operative memory bank 111-114 of the memory 115.

An interconnection circuit 108 is operatively coupled between the memory 115 and the address translation circuits 105 and 106 to provide address and data bus interface for memory read and write operations initiated by one or both of the processors 101 and 102. The interconnection circuit 108 can include any suitable digital logic circuits (not shown), which can be fixed, programmed or programmable, or combinations thereof.

In operation, one of the processors 101, 102 initiates a read and/or write operation, and an address is provided by the processor 101, 102 to the corresponding address translation circuit 105, 106, which selectively translates the received address into another address corresponding to a non-faulty one of the memory banks 111-114. This arrangement allows configuration of the address translation circuitry 105, 106 to allow seamless operation where one or more of the memory banks 111-114 is faulty (e.g., does not pass a manufacturing memory test), but the electronic device 100 can operate with fewer than all the memory banks 111-114.

In the illustrated example, the electronic device 100 also includes a further memory 110 that provides nonvolatile storage. In one example, the memory 110 is or includes flash memory or other non-volatile memory registers. In this or another example, the memory 110 includes one or more one-time programmable elements, such as an e-fuse. As shown in FIG. 1, in certain examples, the device identifier 104 can be stored in the memory 110 alone or in combination with storage of the identifier 104 in the ROM 103. In another implementation, the identifier 104 is stored in the memory 110 and may or may not be stored in the ROM 103.

The system of FIG. 1 also includes boot loader memory 116, that can be separate from the electronic device 100. The boot loader memory 116 includes boot loader firmware 117 (e.g., labeled B-L F/W), including processor executable program instructions for performing startup operations when the electronic device 100 is powered up.

The example electronic device 100 of FIG. 1 also includes address translation data 118 (e.g., labeled “RAT DATA”) stored in the electronic device 100. In one example, the address translation data 118 identifies a non-faulty one of the memory banks 111-114 of the memory 115. In one implementation, the address translation data 118 is stored in the memory 110 along with the device identifier 104. In this or another implementation, the address translation data 118 can be stored in the ROM 103 as shown in FIG. 1. In a further implementation, the address translation data 118 may be stored in the ROM 103 and may or may not be stored in the memory 110.

The address translation circuitry 105, 106 is configurable according to the device identifier 104 stored in the ROM 103 and/or the memory 110. FIG. 1A shows an example implementation of the address translation circuits 105 and 106 configured by an address lookup table 119 in the translation data. In one example, the lookup table 119 includes an integer number n region configuration data structures 120, 125, where n corresponds to the integer number of n RAM banks 111-114 in FIG. 1, although not a requirement of all possible implementations. In the illustrated example, the first region configuration data structure 120 includes one or more input addresses 121, one or more output addresses 122 that individually correspond to one of the input addresses 121, a region size value 123, and region control data 124 that correspond to a first region (e.g., a first one of the RAM banks 111-114 of FIG. 1). The second region configuration data structure 125 shown in FIG. 1A includes one or more input addresses 126, one or more output addresses 127 that individually correspond to one of the input addresses 126, a region size value 128, and region control data 129 associated with the n^{th} region (e.g., the n^{th} RAM bank 114).

The address translation circuitry 105, 106 operates in real-time or near real-time, and provides a low-cost address translation feature for the electronic device 100 that enables operation of one or more processors 101, 102 in conjunction with a multi-bank memory 115 having one or more of the RAM banks 111-114 unavailable, for example, due to faulty operation identified during manufacturing memory testing of the electronic device 100. In one implementation, the address translation circuitry 105, 106 translates memory addresses from a shared code/data address space to a CPU unique address space tailored by configuration via the address translation data 118 for one or more processors 101, 102 of the electronic device 100. In one example, the address translation circuits 105, 106 provide deterministic low latency (e.g., 1-2 cycles) address translation based on the look up table 119. In one example, the individual address translation circuits 105 and 106 each accommodate a finite number of regions (e.g., 4 to 8 or other suitable number of banks in one implementation) for a multi-level memory hierarchy (e.g., three levels L1, L2 and L3).

The device identifier 104 stored in the electronic device 100 (e.g., in a second memory such as in the ROM 103 and/or in the memory 110) is readable by either or both of the processors 101 and 102. In one implementation, moreover, the device identifier 104 can be stored in a programmed fuse 110 (e.g., e-fuse) or other one-time programmable storage element of the electronic device 100. The device identifier 104 identifies one or more non-faulty memory banks 111, 112, 113 and 114 of the memory 115 in any suitable manner, such that the processors 101 and/or 102 can determine the operational status (e.g., faulty/unavailable or non-faulty/available) of each individual memory bank 111, 112, 113 and 114. In one example, the device identifier 104 is a part number with a value that corresponds to a predetermined number and identity of one or more non-faulty memory banks 111-114. In another example, the device identifier 104 includes a separate status bit for each of the memory banks 111-114, with each bit having a binary value indicating whether the corresponding memory bank 111-114 is faulty or non-faulty.

In certain implementations, the device identifier 104 is evaluated, for example, during boot up processing or startup of the electronic device 100 in order to facilitate configuration or programming of the address translation circuits 105, 106 based on the indication of the device identifier 104 as to which memory banks 111-114 can be used for operations of the electronic device 100. The individual address translation circuits 105 and 106 are operatively coupled to the respective processors 101 and 102 as well as to the memory 115. The address translation circuits 105-106 are configured to translate an address of a faulty one of the memory banks 111-114 of the memory 115 to an address of a non-faulty one of the memory banks 111-114. In one example, the address translation circuits 105 and 106 are configured to translate an address of a faulty one of the memory banks 111-114 to an address of a non-faulty one of the memory banks 111-114 of the same size and same latency.

In certain implementations, the processors 101 and 102 can execute the program instructions (e.g., according to the boot loader firmware 117 and/or the ROM firmware 107 in FIG. 1) to configure the address translation circuits 105 and 106. In one example, the address translation circuits 105 and 106 are configured based on the address translation data 118 stored in the electronic device 100 (e.g., such as the look up table 119 of FIG. 1A). In certain implementations, the address translation data 118 identifies a non-faulty one of the memory banks 111-114 of the memory 115. For example, the lookup table 119 region control data 124, 129 can identify one or more non-faulty memory banks 111-114 of the memory 115, such as faulty or non-faulty entries for the individual memory banks 111-114.

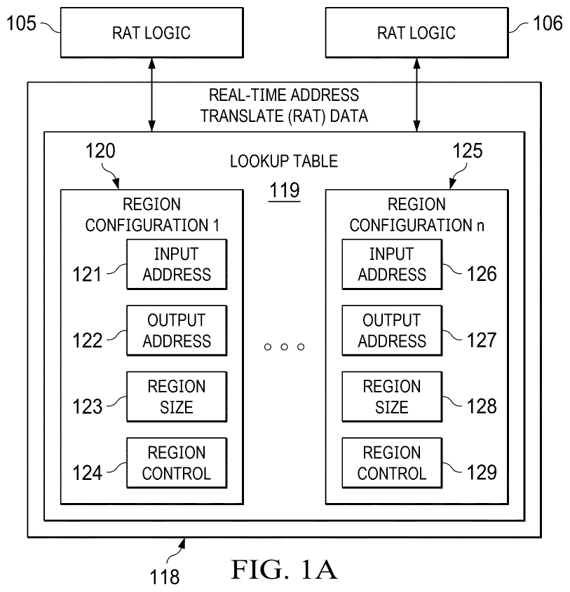

FIG. 2 shows an example electronic device manufacturing method 200 including with memory self testing and device classification based on a memory test result. In one example, the method 200 includes initial programming at 202 in FIG. 2 of one or more memories, such as a fuse or fuses (e.g., c-fuse), non-volatile or flash registers of the memory 110 and/or initial programming of the ROM 103 in FIG. 1.

At 204 in FIG. 2, the method 200 includes RAM memory testing (e.g., enhanced modular RAM testing) to evaluate two or more of the memory banks 111-114 in the electronic device 100 of FIG. 1. The memory testing at 204 can include any form of read and/or write operations to evaluate the individual memory banks 111-114 of the memory 115. The testing at 204 determines a pass or fail result for each memory bank 111-114.

A determination is made at 206 in FIG. 2 as to whether all the memory banks 111-114 passed the test. If so (YES at 206), the method 200 proceeds to 208 and the device ID is stored in the electronic device. In one example, an e-fuse of the memory 110 is programmed at 208 to indicate a first device ID (e.g., a device part number) that corresponds to a device with all the memory banks 111-114 being non-faulty. The electronic device 100 can then be shipped to a customer at 210 in FIG. 2.

If any of the memory banks 111-114 failed the testing at 204 (NO at 206), a determination is made at 212 as to whether the memory 115 of the electronic device 100 has fewer than a predetermined number of working banks 111-114 to be classified as a working device with a corresponding part number. If so (YES at 212), the device is scrapped at 214 as not having enough working RAM banks 111-114 to support the minimum operations of a valid part number.

If a sufficient number of the memory banks 111-114 passed the memory test at 204 in FIG. 2 (NO at 212), the electronic device 100 is classified at 216 to a different (e.g., second) part number based on the number of non-faulty RAM memory banks 111-114. The determination at 216 includes determining a faulty one of the memory banks 111-114 and a non-faulty one of the memory banks 111-114 of the memory 115 to determine a suitable part number or other device identifier 104 for the tested electronic device 100.

At 218 in FIG. 2, the method 200 in one example further includes processing or otherwise evaluating the memory test results to determine the suitable part number for the electronic device 100 and storing the device identifier 104 in a second memory 103, 110 of the electronic device 100. The device identifier 104 identifies one or more non-faulty memory banks 111-114 of the memory 115. In one example, an e-fuse of the memory 110 is programmed at 218 to indicate the different second device ID 104 (e.g., second part number to indicate a lower RAM size in the device 100) based on the number of non-faulty memory banks 111-114 in the memory 115, where the stored device ID 104 indicates the lower RAM size in the electronic device 100. In this or another example, the device ID 104 can be stored in the ROM 103 of the electronic device 100, alone or in combination with storage in an e-fuse or other portion or type of memory 110 in the electronic device 100.

The method 200 continues at 220 with storing the address translation data 118 in the electronic device 100 for configuring the address translation circuits 105 and 106. In one example, the address translation data 118 is stored at 220 in a second memory (e.g., the ROM 103 and/or the memory 110 of the electronic device 100 in FIGS. 1 and 1A). In one implementation, the storage of the address translation data 118 at 220 includes storing a lookup table 119 in the electronic device 100 with entries for two or more of the memory banks 111-114 of the memory 115. The electronic device 100 can then be shipped to a customer at 210 in FIG. 2.

Implementations of the example method 200 can advantageously enhance production yield and reduce device cost by selectively classifying devices with one or more faulty memory banks 111-114 to a different part number if the minimum required non-faulty memory is available, rather than scrapping parts that have some faulty and some non-faulty memory banks 111-114. In certain implementations, the method can be performed automatically, for example, using built in self testing features of the electronic device 100. In one example, the manufacturing test system of FIG. 1 uses one or both of the processors 101 and 102 to perform write and read operations to test two or more of the n memory banks (e.g., 111-114) at 204 in FIG. 2, for example, by executing firmware 107, 117 of the electronic device 100. The processor or processors 101, 102 in one example determine one or more faulty memory banks 111-114 and any non-faulty memory banks 111-114 of the memory 115 (e.g., at 206, 212 in FIG. 2) during manufacturing, and store the device identifier 104 (e.g., in memory 103 and/or 110) of the electronic device 100 that identifies the non-faulty memory bank(s) 111-114 (e.g., at 218 in FIG. 2).

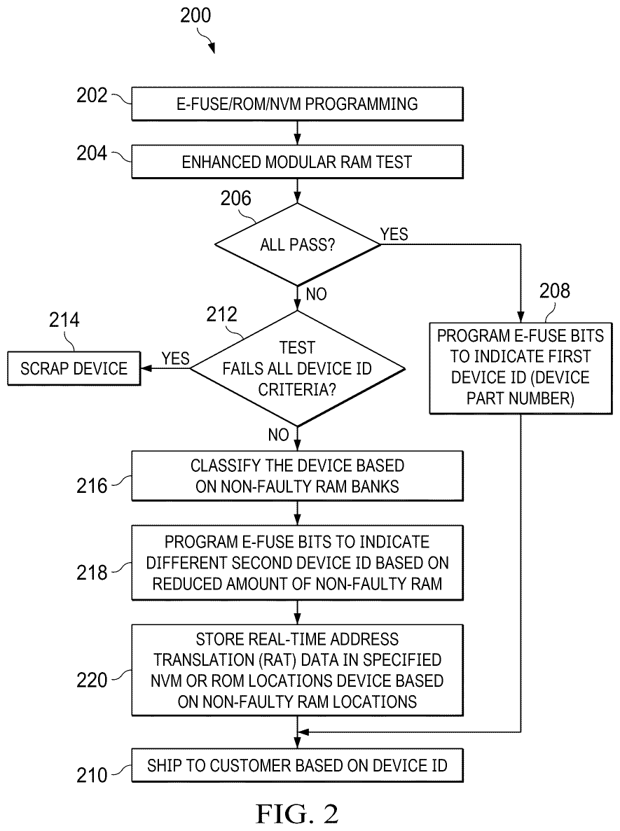

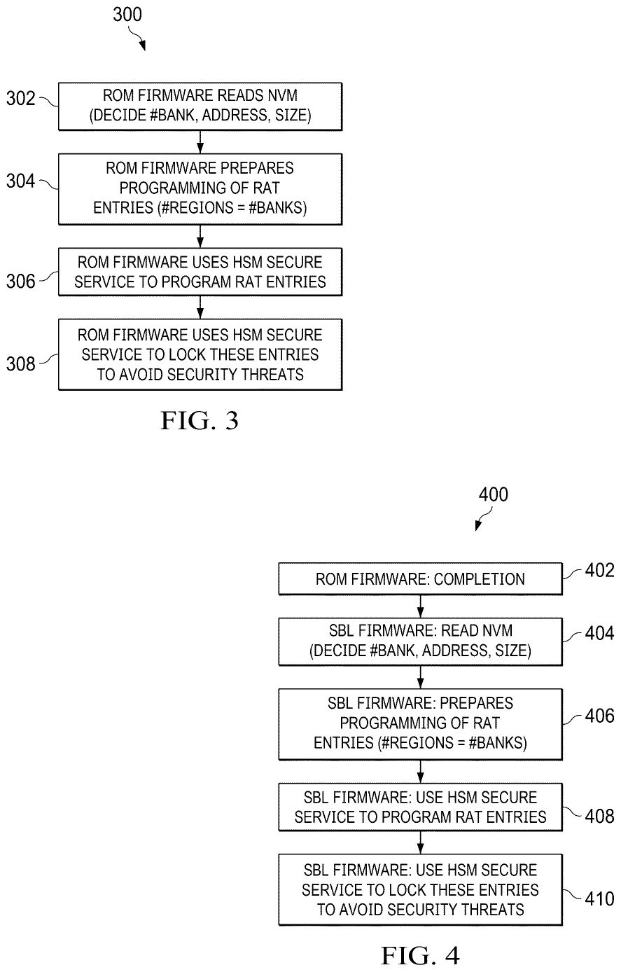

Referring also to FIGS. 3 and 4, in certain examples, one or both of the processors 101 and 102 are configured to execute firmware, such as ROM firmware 107 and/or bootloader firmware 117 in FIG. 1, or other program instructions associated with the electronic device 100, during boot up or startup operations. FIG. 3 shows a ROM firmware address translation circuit configuration method 300 (e.g., performed by a processor 101 and/or 102 executing ROM firmware 107 in FIG. 1), and FIG. 4 shows a boot loader firmware address translation circuit configuration method 400, which can be performed in certain examples by a processor 101 and/or 102 by executing bootloader firmware 117 in FIG. 1.

At 302 in the example of FIG. 3, one or both of the processors 101 and 102 execute program instructions from the ROM firmware 107 to read the device identifier 104 from the ROM 103 and/or from the memory 110 and decide or otherwise determine the number of non-faulty memory banks 111-114, addresses of the non-faulty banks 111-114 and sizes of the non-faulty banks based on the device identifier 104. At 304, the one or both of the processors 101 and 102 execute program instructions from the ROM firmware 107 to prepare programming of one or both of the address translation circuits 105 and 106 including determining a number of regions and banks 111-114 which are non-faulty.

At 306, one or both of the processors 101 and 102 execute program instructions from the ROM firmware 107 to program one or both of the address translation circuits 105 and 106 of the electronic device 100 based on the device identifier 104. In one example, the processors 101 and 102 execute program instructions from the ROM firmware 107 to program one or both of the address translation circuits 105 and 106 using secure services of a hardware secure module (HSM) at 306 (e.g., storing the address translation data 118 in the ROM 103 and/or in the memory 110 of the electronic device 100). At 308, in one example, the processors 101 and 102 execute program instructions from the ROM firmware 107 to lock the address translation data 118 in the ROM 103 and/or in the memory 110, for example, using HSM secure services to prevent or avoid re-programming of these entries by a user or non-secure code to mitigate or avoid security threats.

FIG. 4 illustrates a boot loader firmware example 400 implemented by a processor, such as one or both of the processors 101 and 102 in FIG. 1 by executing bootloader firmware 117 in FIG. 1. In one example, the ROM firmware is programmed at 402 (e.g., firmware 107 in the ROM 103 in FIG. 1). At 404 in FIG. 4, one or both of the processors 101 and 102 execute program instructions from the bootloader firmware 117 (e.g., secondary bootloader or “SBL”) to read the device identifier 104 from the ROM 103 and/or from the memory 110 and decide or otherwise determine the number of non-faulty memory banks 111-114, addresses of the non-faulty banks 111-114 and sizes of the non-faulty banks based on the device identifier 104. At 406 in FIG. 4, the one or both of the processors 101 and 102 execute program instructions from the bootloader firmware 117 to prepare programming of one or both of the address translation circuits 105 and 106 including determining a number of regions and banks 111-114 which are non-faulty.

At 408 in FIG. 4, one or both of the processors 101 and 102 execute program instructions from the bootloader firmware 117 to program one or both of the address translation circuits 105 and 106 of the electronic device 100 based on the device identifier 104. In one example, the processors 101 and 102 execute program instructions from the bootloader firmware 117 to program one or both of the address translation circuits 105 and 106 using secure services of a hardware secure module (HSM) at 408 (e.g., storing the address translation data 118 in the ROM 103 and/or in the memory 110 of the electronic device 100). At 410 in FIG. 4 in one example, the processors 101 and 102 execute program instructions from the bootloader firmware 117 to lock the address translation data 118 in the ROM 103 and/or in the memory 110, for example, using HSM secure services to prevent or avoid re-programming of these entries by a user or non-secured code to mitigate or avoid security threats.

The production systems and manufacturing methods provide a solution to low yield for devices including integrated RAM or other banks 111-114 of memory 115 facilitated by enhanced production engineering (PE) work flows for producing system on chip (SoC) devices or other integrated circuits, as well as software enhancements for intelligent part numbering to identify a particular device identifier 104 based on memory test results during manufacturing. The described solutions help increase yield of electronic device manufacturing by mapping devices with one or more faulty RAM banks 111-114 to a different second (e.g., lower) RAM size part number 104.

In case of failure of one or more given memory banks 111-114, the max part can be derated to a lower part number (with a lower RAM Specification) and shipped rather than scrapping the tested device 100. The device 100 includes on-board real time address translation (RAT) logic circuitry 105, 106 to remap any RAM bank addresses to another RAM Bank of the same size and same latency to the processors 101 and/or 102. This approach allows, for example, reservation of one or more RAM memory banks or regions to support any needed remapping of defective or faulty banks 111-114 or portions thereof in case of a lower specification of part number or device identifier 104. The illustrated examples also provide software to support the address remapping based on the device identifier 104 to facilitate the use of the address translation circuits 105, 106, for example, by ROM or bootloader (e.g., SBL). Described examples also provide for automated programming or configuration of the adds translation circuits 105, 106 using HSM or other secure services and subsequent locking to prevent re-programming after the device identifier 104 and the address translation data 118 have been determined and stored in the electronic device 100.

The manufacturing yield enhancement advantages cam be particularly pronounced in the fabrication of automotive electronic devices, where many modern automotive ICs have internal memory and memories are the highest contributors to yield loss/fallout, particularly for wide temperature operating ranges (e.g., junction temperatures θj up to 165 degrees C.) and SRAM fallout generally increases approximately exponentially at high temperatures.

Modifications are possible in the described examples, and other implementations are possible, within the scope of the claims.

What is claimed is:

1. An electronic device, comprising:
a processor;
a memory having a first memory bank and a second memory bank; and
a device identifier stored in the electronic device and readable by the processor to identify a non-faulty one of the memory banks of the memory.

2. The electronic device of claim 1, wherein the memory is a first memory, and the device identifier is stored in a second memory of the electronic device.

3. The electronic device of claim 1, wherein the device identifier is stored in a programmed fuse of the electronic device.

4. The electronic device of claim 1, further comprising an address translation circuit operatively coupled to the processor and the memory and configured to translate an address of a faulty one of the memory banks of the memory to an address of the non-faulty one of the memory banks of the memory.

5. The electronic device of claim 4, wherein the address translation circuit is configured based on address translation data stored in the electronic device.

6. The electronic device of claim 5, wherein the memory is a first memory, and the address translation data is stored in a second memory of the electronic device.

7. The electronic device of claim 5, wherein the address translation data identifies a non-faulty one of the memory banks of the memory.

8. The electronic device of claim 5, wherein the address translation data includes a lookup table with entries for the first and second memory banks of the memory.

9. The electronic device of claim 4, wherein the address translation circuit is configured to translate an address of a faulty one of the memory banks of the memory to an address of the non-faulty one of the memory banks of the memory of the same size and same latency.

10. The electronic device of claim 4, wherein the memory is a first memory, the electronic device further comprises a second memory, and the processor executes program instructions of the second memory to configure the address translation circuit.

11. A method, comprising:
testing a first memory bank and a second memory bank of a memory in an electronic device;
determining a faulty one of the memory banks of the memory and a non-faulty one of the memory banks of the memory; and
storing a device identifier in the electronic device that identifies the non-faulty one of the memory banks of the memory.

12. The method of claim 11, wherein the memory is a first memory, and storing the device identifier in the electronic device includes storing the device identifier in a second memory of the electronic device.

13. The method of claim 11, wherein storing the device identifier in the electronic device includes programming a fuse of the electronic device.

14. The method of claim 11, further comprising storing address translation data in the electronic device for configuring an address translation circuit of the electronic device.

15. The method of claim 14, wherein the memory is a first memory, and storing the address translation data in the electronic device includes storing the address translation data in a second memory of the electronic device.

16. The method of claim 14, wherein storing the address translation data in the electronic device includes storing a lookup table in the electronic device with entries for the first and second memory banks of the memory.

17. The method of claim 14, further comprising, executing firmware in a read only memory of the electronic device to:
read the device identifier in the electronic device; and
program an address translation circuit of the electronic device based on the device identifier.

18. The method of claim 14, further comprising, executing boot loader firmware to:
read the device identifier in the electronic device; and
program an address translation circuit of the electronic device based on the device identifier.

19. A system, comprising:
a memory having a first memory bank and a second memory bank in an electronic device; and
a processor configured to: test the first memory bank and the second memory bank;
determine a faulty one of the memory banks of the memory and a non-faulty one of the memory banks of the memory; and
store a device identifier in the electronic device that identifies the non-faulty one of the memory banks of the memory.

20. The system of claim 19, wherein the processor is further configured to store address translation data in the electronic device for configuring an address translation circuit of the electronic device.
